(19) United States
(12) Patent Application Publication
(10) Pub. No.: US 2011/0073967 A1
(43) Pub. Date: Mar. 31, 2011

(54) APPARATUS AND METHOD OF FORMING A MEMS ACOUSTIC TRANSDUCER WITH LAYER TRANSFER PROCESSES

(75) Inventors: Li Chen, Arlington, MA (US); Kuang Yang, Newton, MA (US)

(73) Assignee: ANALOG DEVICES, INC., Norwood, MA (US)

(21) Appl. No.: 12/870,266

(22) Filed: Aug. 27, 2010

Related U.S. Application Data
(60) Provisional application No. 61/237,982, filed on Aug. 28, 2009.

(51) Int. Cl. H01L 29/84; H01L 21/02

(52) U.S. Cl. 257/416; 438/53; 257/E29.324; 257/E21.002

(57) ABSTRACT

A method of forming a MEMS microphone forms circuitry and first MEMS microstructure on a first wafer in a first process, and second MEMS microstructure on a second wafer in a second process. The first process is thermally isolated from the second process. The method also layer transfers the second MEMS microstructure onto the first wafer. The first MEMS microstructure and second MEMS microstructure thus form a variable capacitor that communicates with the circuitry on the first wafer.

### PRIORITY

This patent application claims priority from provisional U.S. patent application No. 61/237,982, filed Aug. 28, 2009, entitled, “HIGH PERFORMANCE INTEGRATED MICROPHONE EMPLOYING LAYER TRANSFER TECHNIQUE,” and naming Li Chen and Kuang Yang as inventors, the disclosure of which is incorporated herein, in its entirety, by reference.

### TECHNICAL FIELD

The invention generally relates to microelectromechanical systems (MEMS) and, more particularly, the invention relates to methods of forming a MEMS acoustic transducer.

### BACKGROUND ART

Condenser microphones, such as MEMS microphones, typically have associated detection circuitry that detects diaphragm deflections and transmits such deflections to other circuitry for further processing. Forming such circuitry on the same die as the microphone, however, generally presents a number of challenges.

### SUMMARY OF THE INVENTION

In accordance with one embodiment of the invention, a method of forming a MEMS acoustic transducer forms circuitry and first MEMS microstructure on a first wafer in a first process, and second MEMS microstructure on a second wafer in a second process. The first process is thermally isolated from the second process. The method also layer transfers the second MEMS microstructure onto the first wafer. The first MEMS microstructure and second MEMS microstructure thus form a variable capacitor that communicates with the circuitry on the first wafer.

The first MEMS microstructure may have a first capacitive plate, and the second MEMS microstructure may have a second capacitive plate. The first and second capacitive plates thus form the variable capacitor. For example, the first capacitive plate may form a backplate and the second capacitive plate may form a diaphragm.

Some embodiments layer transfer by bonding the second wafer to the first wafer, and removing at least one entire layer of the second wafer after bonding. Moreover, the first MEMS microstructure and second MEMS microstructure both may be formed at least in part from a silicon-based material. To that end, the first wafer may include a SOI wafer while the second wafer may include at least one of polysilicon, single crystal silicon, silicon carbide, or silicon germanium. The method also may release at least the second MEMS microstructure after layer transferring the second MEMS microstructure onto the first wafer.

In accordance with another embodiment of the invention, a method of forming a MEMS microphone forms circuitry and a semiconductor backplate on a first wafer, and a semiconductor diaphragm on a second wafer. The method then forms a variable capacitor on the first wafer by layer transferring the semiconductor diaphragm onto the first wafer. The variable capacitor includes the backplate and diaphragm to form a MEMS microphone. The capacitor is electrically connected with the circuitry.

In accordance with other embodiments of the invention, a method of forming a MEMS microphone forms circuitry and first MEMS microstructure on a first wafer, and a semiconductor film on a second wafer. The method micromachines the film on the second wafer to form second microstructure, and forms a variable capacitor on the first wafer by layer transferring the second MEMS structure onto the first wafer. The variable capacitor includes the first MEMS structure and the second MEMS structure and is electrically connected with the circuitry.

In accordance with yet other embodiments of the invention, a MEMS microphone has a backplate formed from single crystal silicon, and circuitry formed on the single crystal backplate. The microphone also has a diaphragm coupled with the backplate that forms a variable capacitor with the backplate. The diaphragm also is formed from single crystal silicon.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a perspective view of a MEMS microphone that may be formed in accordance with illustrative embodiments of the invention.

FIG. 2 schematically shows a cross-sectional view of the MEMS microphone of FIG. 1 across line B-B.

FIG. 3 schematically shows a cross-sectional view of an alternative embodiment that may be formed in accordance with illustrative embodiments of the invention.

FIG. 4 shows a process of fabricating a MEMS microphone in accordance with illustrative embodiments of the invention.

FIG. 5 schematically shows a cross-sectional view of a silicon-on-insulator wafer that may be used by the process of FIG. 4 to form either the backplate or the diaphragm.

FIG. 6 schematically shows a cross-sectional view of a die or wafer formed by step 400A of FIG. 4.

FIG. 7 schematically shows a cross-sectional view of a die or wafer formed by step 400B of FIG. 4.

FIG. 8 schematically shows a cross-sectional view of a die or wafer formed by step 400B of FIG. 4 in accordance with alternative embodiments of the invention.

### DESCRIPTION OF ILLUSTRATIVE EMBODIMENTS

Illustrative embodiments fabricate a MEMS microphone with integrated circuitry (or other circuitry) on a single die. To that end, various embodiments form the variable capacitor microstructure using layer transfer techniques. Accordingly, steps requiring high temperatures, such as those for forming a flexible diaphragm, can be performed away from temperature sensitive circuitry. Details of illustrative embodiments are discussed below.

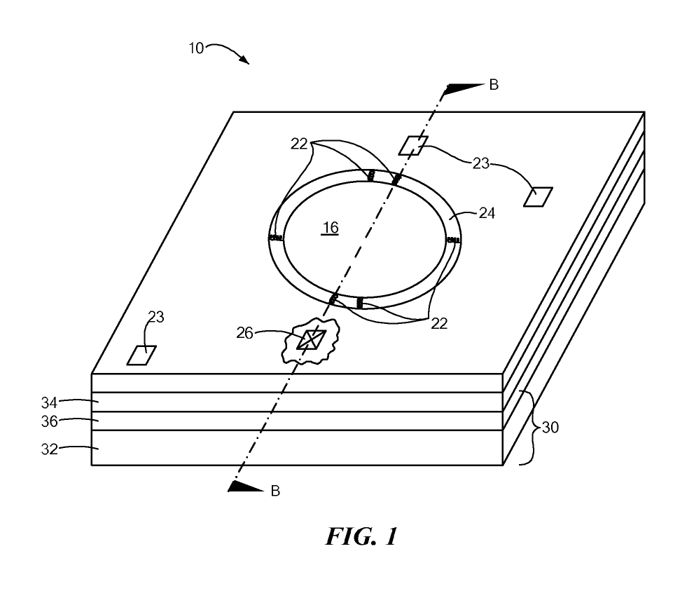

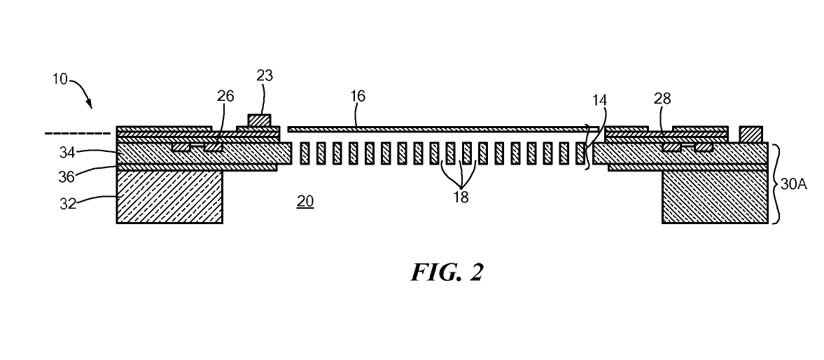

FIG. 1 schematically shows a top, perspective view of a MEMS microphone 10 (also referred to as a “microphone chip 10”) that may be fabricated using layer transfer processes; namely, in accordance with illustrative embodiments of the invention. FIG. 2 schematically shows a cross-sectional view of the same microphone 10 across line B-B of FIG. 1.

Among other things, the microphone 10 includes a static backplate 12 that supports and forms a variable capacitor 14 with a flexible diaphragm 16. In illustrative embodiments, the backplate 12 and diaphragm 16 each are formed from single crystal silicon (e.g., the top layer of a silicon-on-insulator wafer, discussed below). Alternatively, the diaphragm 16 is formed from a film of silicon-based material, such as polysilicon, silicon carbide, or silicon germanium. In a similar manner, other types of materials can form the backplate 12. For example, the backplate 12 can be formed from a relatively low temperature film, such as silicon germanium. If thermal budget is not a primary issue, the backplate 12 can be formed from high temperature materials, such as polysilicon, silicon carbide, or silicon germanium.

To facilitate operation, the backplate 12 has a plurality of through-hole apertures (“backplate apertures 18”) that lead to a backside cavity 20. Springs 22 movably connect the diaphragm 16 to a static/stationary portion of the microphone 10, which includes a substrate that at least in part includes the backplate 12. The springs 22 effectively form a plurality of openings 24 that permit at least a portion of the audio signal to pass through the microphone 10. These openings 24 may be any reasonable shape, such as in the shape of a slot, round hole, or some irregular shape.

The microphone 10 also includes circuitry 26 that cooperates with the variable capacitor 14 to convert audio signals incident upon the diaphragm 16 into electronic signals. The circuitry 26 is shown in a partial cutaway view on FIG. 1, and within the substrate of FIG. 2. Among other things, the circuitry 26 may provide a voltage bias for the backplate 12 and diaphragm 16, and convert the variable capacitance into an electronic signal. In illustrative embodiments, the circuitry 26 is formed primarily from CMOS circuitry, although other types of circuitry may suffice. Metal contact pads 23 on the top surface of the microphone 10 enable electrical access to the circuitry 26 and relevant microstructure.

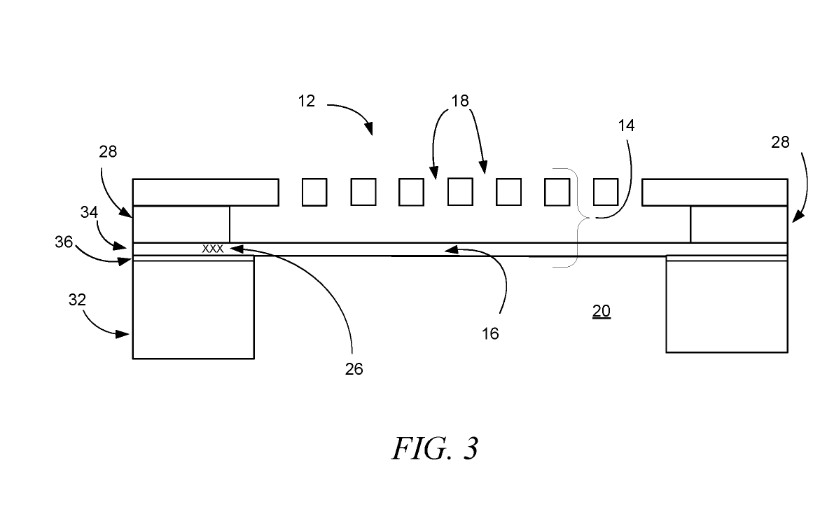

FIG. 3 schematically shows a cross-sectional view of an alternative embodiment of the microphone 10. Specifically, this embodiment of the microphone 10 positions the diaphragm 16 between the backplate 12 and the backside cavity 20. As with the embodiments of FIGS. 1 and 2, the backplate 12 and/or the diaphragm 16 can be formed from any one of a variety of materials, such as single crystal silicon, polysilicon, silicon carbide, or silicon germanium.

Illustrative embodiments first at least in part form critical microstructure, such as the variable capacitor, across two separate wafers (e.g., two silicon-on-insulator wafers, also referred to as “SOI wafers”), and then bond those two wafers together using a low temperature process. Alternately, the process may bond the wafers prior to the complete fabrication of at least one of the wafers (i.e., when some fabrication steps remain for at least one of the wafers). In illustrative embodiments, each wafer is an SOI wafer, although various embodiments are not necessarily limited to SOI wafers. Discussion of SOI wafers thus is for exemplary purposes only.

A low temperature bond secures the wafers together; preferably lower than the temperature at which a MEMS structure or circuit elements 26 may be damaged. For example, in various embodiments, the bond may be fabricated under pressure in a bonder at temperatures of between about 200 to 400 degrees Celsius. Accordingly, illustrative embodiments permit the use of more circuitry 26 sensitive to higher temperatures, such as the deposition temperature of polysilicon.

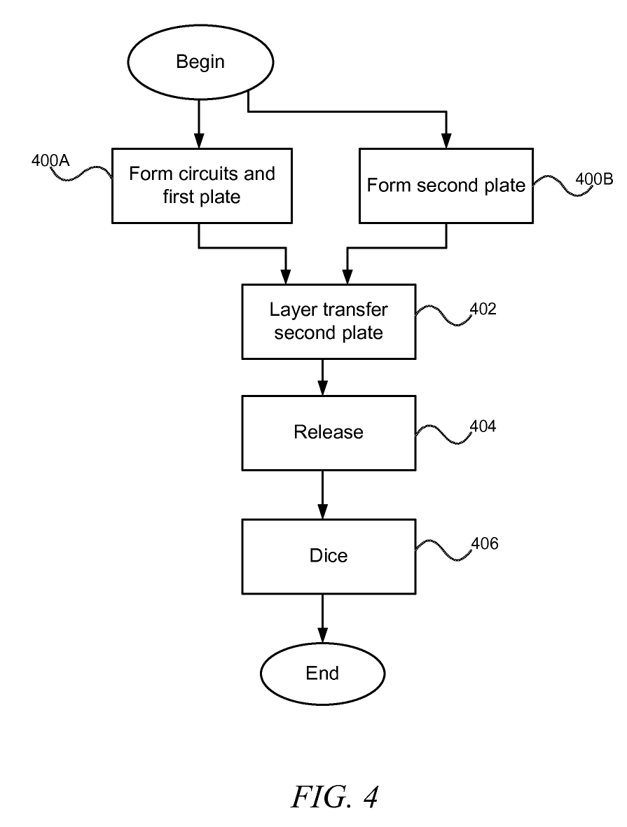

To those ends, FIG. 4 shows a process of forming the MEMS microphone 10 of FIGS. 1 and 2 in accordance with illustrative embodiments of the invention. It should be noted that for simplicity, this described process is a significantly simplified version of an actual process used to form the MEMS microphone 10. Accordingly, those skilled in the art would understand that the process may have additional steps not explicitly shown in FIG. 4. Moreover, some of the steps may be performed in a different order than that shown, or at substantially the same time. Those skilled in the art should be capable of modifying the process to suit their particular requirements.

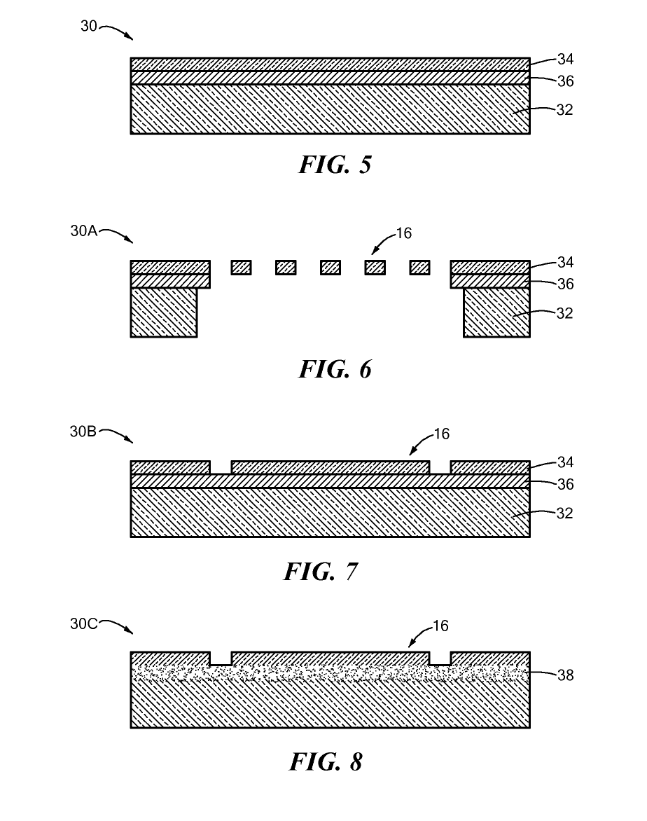

The process begins at steps 400A and 400B by processing, in parallel, two different silicon-on-insulator wafers in separate processes. Specifically, FIG. 5 schematically shows a cross-sectional view of a silicon-on-insulator wafer 30, which has a silicon base layer 32 (often referred to as the “handle layer 32”) for supporting a top, silicon device layer 34 and insulator layer 36 (e.g., an oxide). As known by those skilled in the art, the insulator layer 36 secures the device layer 34 to the base layer.

More particularly, step 400A forms circuitry 26 and a first plate of the variable capacitor 14 on a first SOI wafer 30A, while step 400B forms a second plate of the variable capacitor 14 on a second SOI wafer 30B. For example, in the embodiment shown in FIG. 2, the first plate is the backplate 12 while the second plate is the diaphragm 16. FIG. 6 schematically shows the (partially processed) SOI wafer 30A having the circuitry 26 and the backplate 12, while FIG. 7 schematically shows the (partially processed) SOI wafer 30B having the diaphragm 16. As shown in FIG. 6, the circuitry 26 may be formed about the backplate 12; namely, circumferentially outward of the backplate 12. Although the figures show the circuitry 26 schematically at one spot only, it may be distributed across the wafer 30A in appropriate locations.

It is important to note that these two processes are separate and thus, thermally isolated, i.e., heat produced to form either one of those components does not materially impact the temperature for forming the other component. Accordingly, the diaphragm 16 and springs 22 may be formed from high-temperature processes and still not impact/damage the circuitry 26 on the SOI wafer 30A formed by step 400A.

As shown in the figures discussed above, steps 400A and 400B can be formed in parallel/generally at the same time. Those skilled in the art nevertheless can perform those steps in series, with either step being performed first.

The process then continues to step 402 by layer transferring the second plate (the diaphragm 16) onto the SOI wafer 30A having the circuitry 26 and backplate 12. To that end, step 402 bonds the SOI wafer 30B having the diaphragm 16 to the SOI wafer 30A having the backplate 12 and circuitry 26.

More specifically, a low temperature bonding medium 28 secures the SOI wafer 30B having the diaphragm 16 in a manner that positions the diaphragm 16 adjacent to, but spaced from, the backplate 12 (as shown in FIG. 2). Those skilled in the art can select the appropriate bonding medium 28, which may include a metal, adhesive, or oxide. It nevertheless should be noted that other bonding media may provide sufficient results. Discussion of specific bonding media thus is illustrative and not intended to limit various embodiments.

The thickness of the bonding medium 28 is important in determining the capacitance of the variable capacitor 14. In the mass production of such microphone systems 10, the variation in the gap between the backplate 12 and the diaphragm 16 illustratively may be less than about five percent (5%) of the nominal gap.

To complete the layer transfer process, step 402 removes portions of the second wafer 30B. In illustrative embodiments, the removed portions of the second wafer 30B are those that are farthest from the bonding point of the two wafer 30A and 30B (e.g., the outside of the so-called sandwich). For example, entire planes of the wafer 30B having the diaphragm 16 may be removed (e.g., the handle layer 32 and the at least part of the insulator layer 36 between the handle and device layers 32 and 34). Thus, a layer of the second SOI wafer 30B (i.e., the diaphragm 16) effectively has been transferred to the first SOI wafer 30A. The second SOI wafer 30B may thus be referred to as a “donor” wafer 30B.

If, as shown in FIG. 7, the second wafer 30B is an SOI wafer with the diaphragm 16 in the top layer, the process may remove layers of the donor wafer 30B by merely etching away most or all of the insulator layer 36. This effectively removes/detaches the handle layer 32, which is not necessary in the final product. If the second wafer 30B is not an SOI wafer 30, but has a diaphragm 16 supported by a sacrificial layer between the diaphragm 16 and the surface of some substrate, then the process may remove layers of the donor wafer 30B in a similar manner; namely, by etching away the sacrificial layer. Alternately, the portions to be removed may be removed by grinding or etching away some of the silicon with an appropriate acid. Some embodiments may remove portions of the donor wafer 30B by a combination of etching, and grinding, or lapping down the portions to be removed. For example, if the wafer 30B is an SOI wafer, the handle layer 32 may be removed by grinding, thus exposing the insulator layer 36. The insulator layer 36 may then be removed by etching.

Some embodiments may form the diaphragm 16 on a pre-weakened bulk silicon wafer 30C that can be easily cleaved to remove unnecessary portions. FIG. 8 schematically shows one such wafer 30C. Specifically, the wafer 30C of FIG. 8 has hydrogen ions implanted into its interior to form an internal damage plane 38. This damage plane 38 is generally parallel to the surface that supports (or will support) the diaphragm 16. Accordingly, after bonding the two wafers 30A and 30C, the damaged layer may later be cut or severed to separate the remaining substrate from the layer to be transferred.

Such processes, which may be known in the art as “Smart Cut,” are described, for example, in U.S. Pat. No. 5,374,564, or U.S. Pat. No. 5,882,987. As noted above, exemplary processes implant ions, such as hydrogen ions, into the wafer 30C, to create, for example, a hydrogen-rich layer damage plane 38 in the donor wafer 30C prior to bonding the two wafers 30A and 30C. The ions create a region that makes the wafer 30C susceptible to fracture. The crystalline silicon may be fractured along the damage plane 38 through an annealing process to leave behind the diaphragm layer 16.

These processes thus leave a layer (e.g., a diaphragm 16) of the second wafer 30B or 30C bonded to the first wafer, effectively transferring the layer from the donor wafer 30B or 30C to the first wafer 30A. The unused portion of the donor wafer 30B or 30C may be reused if it is thick enough to have a transferable layer fabricated on its face.

It should be noted that steps 400A and 400B may not have fully processed their respective SOI wafers 30A and 30B before the layer transfer step 402. For example, some embodiments fabricate a sacrificial layer, or leave an existing sacrificial layer in place, between the diaphragm 16 and the underlying substrate (e.g., a handle layer 32) until after the donor wafer 30B (or 30C) donates its capacitive plate to the wafer 30A having the circuitry 26 and first plate. In this way, the diaphragm 16 is immobilized after it is formed, and remains immobilized while other processing is performed on the device.

Alternatively, some embodiments skip one or both of steps 400A and 400B. For example, those embodiments may simply transfer an entire layer from the donor wafer 30B or 30C to the main wafer 30A, and then form the microstructure at a later time.

Accordingly, after layer transferring the diaphragm 16, step 404 releases the diaphragm 16 using conventional processes. For example, the process may remove the oxide, polymer, metal, or other sacrificial layer using an appropriate acid or other etchant. The process also may perform some post processing steps, such as polishing surfaces (e.g., through a mechanical grind), releasing additional MEMS structures, or interconnecting circuits. Polishing the surface of the diaphragm 16 that faces the backplate 12 may not be necessary if that surface was acceptably smooth or polished prior to the layer transfer.

The process concludes at step 406 by dicing the wafer structure into individual MEMS microphones 10. At this point, further post-processing steps may be performed before packaging and/or assembly into an end product, such as a computer system or mobile telephone.

Illustrative embodiments may package the microphone chip 10 in any of a variety of different types of packages. One important consideration is the susceptibility of the microphone chip 10 to electromagnetic interference (“EMI”). To protect the microphone chip 10 against EMI, illustrative embodiments use packages that effectively form a Faraday cage around the microphone chip 10. For example, the package may have a base formed from printed circuit board material, such as FR4 or laminate. Alternatively, the base may be formed from leadframe packaging technology, carrier, or ceramic packages. Other embodiments may use wafer level packaging techniques (e.g., using another wafer to cap the variable capacitor and/or other microstructure). For additional examples of microphone packaging, see co-pending U.S. patent application Ser. No. 12/847,682, filed Jul. 30, 2010, entitled “Reduced Footprint Microphone System with Spacer Member Having Through-Hole,” the disclosure of which is incorporated herein, in its entirety, by reference.

It should be reiterated that discussion of the embodiments using two SOI wafers 30A and 30B is illustrative and not intended to limit all embodiments. For example, as noted above, the donor wafer 30B may simply be a bulk silicon wafer or other substrate supporting a thin film of material, such as polysilicon, silicon carbide, or silicon germanium. In a similar manner, the wafer 30A having the circuitry 26 can be something other than an SOI wafer, such as a bulk silicon wafer.

Moreover, also as noted above, discussion of the donor wafer 30B or 30C providing a diaphragm 16 is for simplicity purposes only. Instead, as shown in FIG. 3, the donor wafer 30B or 30C may provide the backplate 12. In fact, some embodiments may form circuitry 26 in the donor wafer 30B or 30C. Alternative embodiments, however, do not have circuitry 26 in either of the wafers 30A and 30B (or on wafers 30A and 30C) and thus, require a separate, off-chip integrated circuit.

Accordingly, various embodiments form a micromachined acoustic sensor, or MEMS transducer, specifically implemented as a condenser microphone. By forming the plates of a single capacitor 14 on two separate wafers 30A and 30B by two separate processes, this microphone 10 can have on-chip circuitry 26 that is not limited by the thermal requirements of the fabrication process. Removing this limitation of the prior art thus gives the microphone designer more flexibility to use a wider variety of circuitry 26. Consequently, the final microphone system 10 can have improved overall performance and additional functionality.

Although the above discussion discloses various exemplary embodiments of the invention, it should be apparent that those skilled in the art can make various modifications that will achieve some of the advantages of the invention without departing from the true scope of the invention.

What is claimed is:

1. A method of forming a MEMS acoustic transducer, the method comprising:
forming circuitry and first MEMS microstructure on a first wafer in a first process;
forming second MEMS microstructure on a second wafer in a second process, the first process being thermally isolated from the second process; and
layer transferring the second MEMS microstructure onto the first wafer, the first MEMS microstructure and second MEMS microstructure forming a variable capacitor that communicates with the circuitry on the first wafer.

2. The method as defined by claim 1 wherein the first MEMS microstructure comprises a first capacitive plate, and the second MEMS microstructure comprises a second capacitive plate, the first and second capacitive plates forming the variable capacitor.

3. The method as defined by claim 2 wherein the first capacitive plate comprises a backplate and the second capacitive plate comprises a diaphragm.

4. The method as defined by claim 1 wherein layer transferring comprises bonding the second wafer to the first wafer, and removing at least one entire layer of the second wafer after bonding.

5. The method as defined by claim 1 wherein the first wafer comprises a SOI wafer.

6. The method as defined by claim 1 wherein the first MEMS microstructure and second MEMS microstructure both are formed at least in part from a silicon-based material.

7. The method as defined by claim 6 wherein the second wafer comprises at least one of polysilicon, single crystal silicon, silicon carbide, or silicon germanium.

8. The method as defined by claim 1 further comprising releasing at least the second MEMS microstructure after layer transferring the second MEMS microstructure onto the first wafer.

9. The apparatus formed by the method of claim 1.

10. A method of forming a MEMS microphone, the method comprising:
forming circuitry and a semiconductor backplate on a first wafer;
forming a semiconductor diaphragm on a second wafer; and
forming a variable capacitor on the first wafer by layer transferring the semiconductor diaphragm onto the first wafer, the variable capacitor comprising the backplate and diaphragm to form a MEMS microphone, the capacitor being electrically connected with the circuitry.

11. The method as defined by claim 10 wherein the first wafer comprises an SOI wafer.

12. The method as defined by claim 10 wherein layer transferring comprises bonding the second wafer to the first wafer, and removing at least one entire layer of the second wafer after bonding.

13. The method as defined by claim 10 wherein the semiconductor diaphragm comprises at least one of polysilicon, single crystal silicon, silicon carbide, and silicon germanium.

14. The method as defined by claim 10 further comprising releasing at least the semiconductor diaphragm after layer transferring the semiconductor diaphragm onto the first wafer.

15. The method as defined by claim 10 wherein the semiconductor backplate is formed in a first process, and the semiconductor diaphragm is formed in a second process, the first process being thermally isolated from the second process.

16. The apparatus formed by the process of claim 10.

17. A MEMS microphone comprising:
a backplate comprised of single crystal silicon;
circuitry formed on the single crystal backplate; and
a diaphragm coupled with the backplate and forming a variable capacitor with the backplate, the diaphragm being comprised of single crystal silicon.

18. The MEMS microphone as defined by claim 17 further comprising a plurality of springs supporting the diaphragm.

19. The MEMS microphone as defined by claim 17 wherein the backplate is formed from a layer of an SOI wafer.
